(19) United States
(12) Patent Application Publication
(10) Pub. No.: US 2025/0081399 A1
(43) Pub. Date: Mar. 6, 2025

(54) LIMITING STRUCTURE AND LIMITING METHOD THEREOF

(71) Applicant: FIVEGRAND INTERNATIONAL CO., LTD., New Taipei City (TW)

(72) Inventor: TING-JUI WANG, New Taipei City (TW)

(73) Assignee: FIVEGRAND INTERNATIONAL CO., LTD., New Taipei City (TW)

(21) Appl. No.: 18/774,958

(22) Filed: Jul. 17, 2024

(30) Foreign Application Priority Data
Aug. 31, 2023 (TW) 112133057

(51) Int. Cl. H05K 7/20; H01L 23/40

(52) U.S. Cl. CPC H05K 7/20509; H05K 7/2049; H01L 23/40

(57) ABSTRACT

A limiting structure and a limiting method thereof are introduced, the limiting structure includes a limiting body, a heat dissipation body and a fastening body. The limiting body is combined with the heat dissipation body; the fastening body is disposed at the limiting structure, or an elastic element or cushioning element is disposed between the fastening body and the limiting structure, the fastening body is used to combine with an object, so that the limiting body is limited to the object, and the limiting structure makes the heat dissipation body have a distance from a heating element of the object.

### CROSS-REFERENCE TO RELATED APPLICATION

This non-provisional application claims priority under 35 U.S.C. § 119 (a) on Patent Application No(s). 112133057 filed in Taiwan, R.O.C. on Aug. 31, 2023, the entire contents of which are hereby incorporated by reference.

### BACKGROUND OF THE INVENTION

### 1. Field of the Invention

The present disclosure provides a limiting structure and a limiting method thereof, and in particular a limiting structure and a limiting method thereof that can be used to combine and separate at least two objects repeatedly and quickly.

### 2. Description of the Related Art

Generally, when combining at least one object, it is usually achieved by locking with screws to combine the object.

In terms of the above-mentioned customary fixing method, although at least one object can be fixed and combined in a manner that is not easy to separate, in addition to causing a situation that is not easy to assemble, at least one object will be difficult to disassemble because of the fixing and combining method of the screws.

### BRIEF SUMMARY OF THE INVENTION

In view of the above prior art, the inventor developed a limiting structure and a limiting method thereof, with a view to completing the quick combination of at least two objects, so as to achieve the effect of combining and separating repeatedly and quickly.

To achieve the above objective and other objectives, the present disclosure provides a limiting structure, including: at least one limiting body, at least one heat dissipation body and at least one fastening body. The limiting body is combined with the heat dissipation body; the fastening body is disposed at the limiting structure, or an elastic element or cushioning element is disposed between the fastening body and the limiting structure, the fastening body is used to combine with an object, so that the limiting structure is limited to the object, and the limiting body makes the heat dissipation body have a distance from a heating element of the object, or the limiting body restricts the elastic force or cushioning force exerted by the heat dissipation body on a heating element, or the limiting body is rotated or moved to make the heat dissipation body elastically pressed downward, pressed downward or contact the heating element for heat dissipation, or the limiting body can release the restriction of elasticity or cushioning force of the heat dissipation body for heat dissipation with the heating element or the limiting body can make the heat dissipation body contact the heating element for heat dissipation.

In the above limiting structure, the limiting body is provided with a body part, the body part is combined with the heat dissipation body, or the body part is integrally formed with the heat dissipation body, or the limiting body is combined with the heat dissipation body.

In the above limiting structure, the limiting body, or a body part of the limiting body or the heat dissipation body is provided with a stopping part, the stopping part stops the limiting body at a blocking position of the object.

In the above limiting structure, the limiting body, or a body part of the limiting body or the heat dissipation body is provided with a restriction part, the restriction part restricts the limiting body at a resisting position or a non-resisting position.

In the above limiting structure, the restriction part is a fastening body, a hole body, a groove body, a convex body, a concave body or a structure that can restrict a position.

In the above limiting structure, the number of the limiting body is two or more, at least one connecting part is respectively disposed between the limiting bodies, so that the limiting bodies are linked with the connecting part.

In the above limiting structure, the limiting bodies therebetween, the limiting bodies and the connecting part therebetween, the limiting bodies and the heat dissipation body therebetween, or the limiting bodies and a body part therebetween are bolted, assembled or axially connected.

In the above limiting structure, the limiting body is blocked against the object, the limiting body is a single-piece structure, or the limiting body is a multi-piece connecting structure.

In the above limiting structure, the heating element is a chip, an IC, a memory, a circuit board or a current device, the object is a circuit board, or a server, a data center, a storage, a computer or a current device, or the heat dissipation body is a heat sink, a liquid cooling device, a radiator or a metal body.

In the above limiting structure, an elastic body is disposed between the limiting body and the heat dissipation body, the elastic body makes the limiting body elastically located in a resisting position or a non-resisting position.

In the above limiting structure, the limiting structure is provided with a safety device, the safety device can actuate with the movement or rotation of the limiting body, so that when the limiting body is limited to that the heat dissipation body has a distance from the heating element, or when the limiting body restricts the elastic force or cushioning force exerted by the heat dissipation body on the heating element, a tool, non-tool or manual control is not stopped to operate the fastening body, or when the limiting body is not limited to that the heat dissipation body has a distance from the heating element, or when the limiting body restricts the elastic force or cushioning force exerted by the heat dissipation body on the heating element, a tool, non-tool or manual control is stopped to operate the fastening body.

In the above limiting structure, the safety device is bolted or assembled to the limiting structure, the limiting body or the heat dissipation body.

In the above limiting structure, the limiting body is a column, a metal body, a plastic body, a rod body, a bolted body or a buckle body, or the fastening body is a threaded body, an elastic fastening body, a rod body, an outer fastening body, an inner fastening body, a fastening body with a limiting height, or the elastic element is a spring, a coil spring, an elastic column or an element with cushioning characteristics.

In the above limiting structure, the fastening body presses down the elastic element or the cushioning element, so that the elastic element or the cushioning element presses down the heat dissipation body to contact the heating element to dissipate heat.

In the above limiting structure, the fastening body is provided with a blocking part, the blocking part restricts a depth, height or stroke of the fastening body fastening into the object, or the blocking part gives the elastic element or the cushioning element storage, setting, reserved height, stroke, pressure height or pressure stroke.

The disclosure further provides a limiting method of a limiting structure, wherein the limiting body is combined with the heat dissipation body with a downward pressure elastic force or with a cushioning element, and combined to the object by the fastening body, so that the limiting body is limited to the object, and the heat dissipation body has a distance from the heating element of the object, or the elastic force or cushioning force exerted by the heat dissipation body on the heating element is restricted, and then the limiting body is rotated or moved, so that the heat dissipation body is elastically pressed downward, pressed downward or contacts the heating element for heat dissipation, or the restriction of elasticity or cushioning force of the heat dissipation body is released for heat dissipation with the heating element or the heat dissipation body is allowed to contact the heating element for heat dissipation.

The disclosure further provides a limiting method of a limiting structure, wherein the limiting body is used to make the heat dissipation body contact the heating element with uniform force, pressure, downward pressure or elastic downward pressure to be used for heat dissipation.

Accordingly, the limiting structure and the limiting method thereof according to the present disclosure can make the heat dissipation body combine or separate the object and the heating element by using the limiting structure, and complete the quick combination of at least two objects, so as to achieve the purpose of combining and separating repeatedly and quickly.

### BRIEF DESCRIPTION OF THE DRAWINGS

FIG. 1 is a schematic view of a using state of a first embodiment of the present disclosure.

FIG. 2 is a schematic outside view of a second embodiment of the present disclosure.

FIG. 3 is a schematic view of a using state of the second embodiment of the present disclosure.

FIG. 4 is a schematic view of a using state of a third embodiment of the present disclosure.

FIG. 5 is a schematic view 1 of a using state of a fourth embodiment of the present disclosure.

FIG. 6 is a schematic view 2 of a using state of the fourth embodiment of the present disclosure.

FIG. 7 is a schematic view of different types of fastening bodies of the present disclosure.

FIG. 8 is a schematic view of a using state of a fifth embodiment of the present disclosure.

### DETAILED DESCRIPTION OF THE INVENTION

To facilitate understanding of the purpose, characteristics and effects of the present disclosure, embodiments together with the attached drawings for the detailed description of the present disclosure are provided as below.

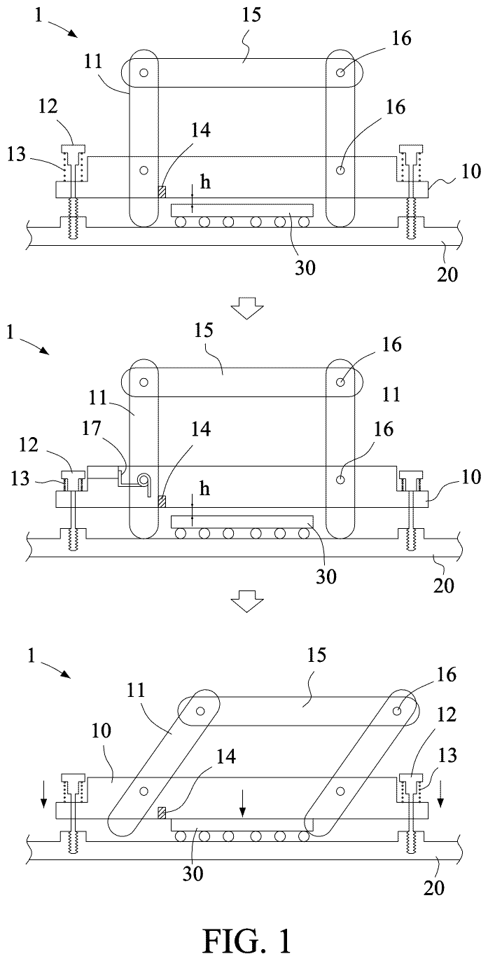

Referring to FIG. 1, as shown in the drawing, the present disclosure provides a limiting structure and a limiting method thereof, the limiting structure 1 includes at least one limiting body 11, at least one heat dissipation body 10 and at least one fastening body 12.

The limiting body 11 is combined with a heat dissipation body 10, the heat dissipation body 10 has elastic force.

The fastening body 12 is disposed at the limiting structure 1, an elastic element 13 (or a cushioning element) is disposed between the fastening body 12 and the limiting structure 1, the fastening body 12 is used to combine with an object 20, so that the limiting body 11 is limited to the object 20, and the limiting structure 1 makes the heat dissipation body 10 have a distance h from a heating element 30 of the object 20, or the limiting structure 1 restricts the elastic force or cushioning force exerted by the heat dissipation body 10 on a heating element 30, and rotates or moves the limiting body 11 to make the heat dissipation body 10 elastically pressed downward or pressed downward to contact the heating element 30 for heat dissipation, or releases the restriction of elasticity or cushioning force of the heat dissipation body 10 for heat dissipation with the heating element 30.

When the limiting structure 1 is used, the limiting method thereof is to combine the limiting body 11 with the heat dissipation body 10 with a downward pressure elastic force (or with a cushioning element), and combined to the object 20 by the fastening body 12, so that the limiting body 11 is limited to the object 20, and the heat dissipation body 10 has a distance h from the heating element 30 on the object 20 by the limiting body 11 directly abutting against the object 20, or the elastic force or cushioning force exerted by the heat dissipation body 10 on the heating element 30 is restricted, and then the limiting body 11 is rotated or moved, so that the heat dissipation body 10 is elastically pressed downward and contacts (or pressed downward to) the heating element 30 for heat dissipation, or the restriction of elasticity or cushioning force of the heat dissipation body 10 is released for heat dissipation with the heating element 30 (or the heat dissipation body 10 is allowed to contact the heating element 30 for heat dissipation), that is, the present disclosure can be used to make the heat dissipation body 10 contact the heating element 30 with uniform force, pressure, downward pressure or elastic downward pressure through the limiting body 11 to be used for heat dissipation. Accordingly, the heat dissipation body 10 can be used to combine or separate the object 20 and the heating element 30 by using the limiting structure 1, and complete the quick combination of at least two objects, so as to achieve the purpose of combining and separating repeatedly and quickly.

In addition to the above embodiment, in one embodiment of the present disclosure, the limiting body 11 (or the heat dissipation body 10) is provided with a stopping part 14, and the stopping part 14 stops the limiting body 11 at a blocking position of the object 20. Accordingly, when the fastening body 12 is combined with the object 20, the limiting body 11 can be positioned at the blocking position by using the stopping of the stopping part 14, so that the heat dissipation body 10 has a distance h from the heating element 30 on the object 20, and then the limiting body 11 is rotated, so that the heat dissipation body 10 is elastically pressed downward and contacts the heating element 30 for heat dissipation. Accordingly, the heat dissipation body 10 can combine or separate the object 20 and the heating element 30 by using the limiting structure 1, and complete the quick combination of at least two objects, so as to achieve the purpose of combining and separating repeatedly and quickly.

In addition to the above embodiments, in one embodiment of the present disclosure, the limiting body 11 is blocked against the object 20, the limiting body 11 may be a single-piece structure, or the limiting body 11 may be a multi-piece connecting structure, and when the number of the limiting body 11 is two or more multi-piece connecting structures, at least one connecting part 15 is respectively disposed between the limiting bodies 11, so that the limiting bodies 11 are linked with the connecting part 15 and form a linkage. Accordingly, the limiting bodies 11 can be rotated, and then the heat dissipation body 10 is elastically pressed downward and contacts the heating element 30 for heat dissipation. Accordingly, the heat dissipation body 10 can combine or separate the object 20 and the heating element 30 by using the limiting structure 1, and complete the quick combination of at least two objects, so as to achieve the purpose of combining and separating repeatedly and quickly.

In addition to the above embodiments, in one embodiment of the present disclosure, the limiting bodies 11 therebetween, the limiting bodies 11 and the connecting part 15 therebetween, the limiting bodies 11 and the heat dissipation body 10 therebetween are bolted, assembled or axially connected by a pivot 16. Accordingly, the limiting bodies 11 can be rotated, and then the heat dissipation body 10 is elastically pressed downward and contacts the heating element 30 for heat dissipation. Accordingly, the heat dissipation body 10 can combine or separate the object 20 and the heating element 30 by using the limiting structure 1, and complete the quick combination of at least two objects, so as to achieve the purpose of combining and separating repeatedly and quickly.

In addition to the above embodiments, in one embodiment of the present disclosure, the heating element 30 may be a chip, an IC, a memory, a circuit board or a current device, and the object 20 may be a circuit board, or a server, a data center, a storage, a computer or a current device, or the heat dissipation body 10 is a heat sink, a liquid cooling device, a radiator or a metal body. Accordingly, the object 20 and the heating element 30 can further meet the needs of practical application.

In addition to the above embodiments, in one embodiment of the present disclosure, an elastic body 17 is disposed between the limiting body 11 and the heat dissipation body 10, and the elastic body 17 makes the limiting body 11 elastically located in a resisting position or a non-resisting position. Accordingly, when the limiting body 11 is limited to the object 20, the elastic force of the elastic body 17 can be used to make the heat dissipation body 10 on the limiting body 11 stably maintained at the distance h from the heating element 30, in order to rotate the limiting body 11 afterwards, and then the heat dissipation body 10 is elastically pressed downward and contacts the heating element 30 for heat dissipation. Accordingly, the heat dissipation body 10 can combine or separate the object 20 and the heating element 30 by using the limiting structure 1, and complete the quick combination of at least two objects, so as to achieve the purpose of combining and separating repeatedly and quickly.

In addition to the above embodiments, in one embodiment of the present disclosure, the limiting body 11 may be a column, a metal body, a plastic body, a rod body, a bolted body or a buckle body. Accordingly, the limiting body 11 can further meet the needs of practical application.

In addition to the above embodiments, in one embodiment of the present disclosure, the elastic element 13 is a spring, a coil spring, an elastic column or an element with cushioning characteristics. Accordingly, the elastic element 13 can further meet the needs of practical application.

In addition to the above embodiments, in one embodiment of the present disclosure, the fastening body 12 presses down the elastic element 13 (or the cushioning element), so that the elastic element 13 presses down the heat dissipation body 10 to contact the heating element 30 to dissipate heat.

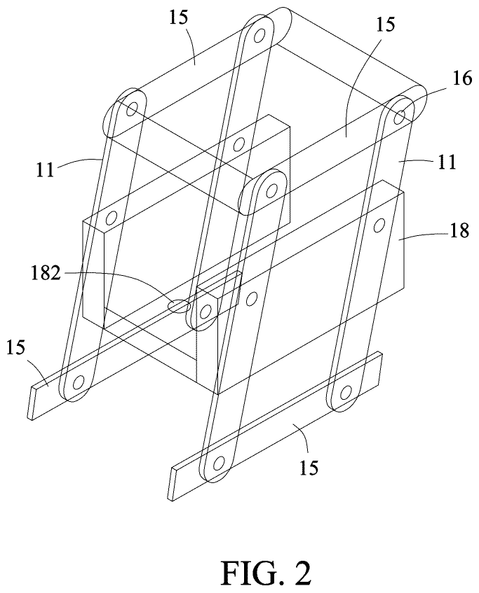

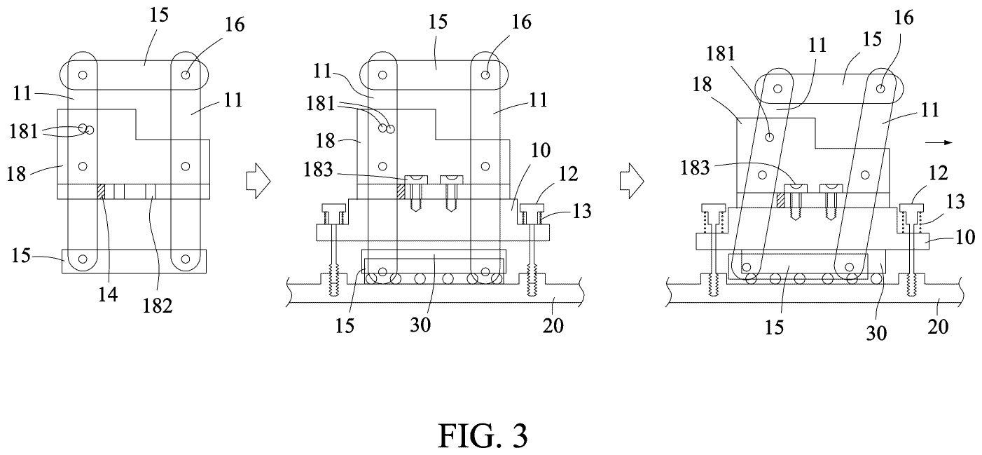

Referring to FIG. 2 to FIG. 3, as shown in the drawings, in addition to the above embodiment, in one embodiment of the present disclosure, the limiting body 11 is provided with a body part 18, and the body part 18 is combined with the heat dissipation body 10 (or the body part 18 is integrally formed with the heat dissipation body 10). Accordingly, the heat dissipation body 10 can be stably disposed to the limiting body 11 by the body 18, or the limiting body 11 can be combined with the heat dissipation body 10.

In addition to the above embodiments, in one embodiment of the present disclosure, the body part 18 (or the heat dissipation body 10) is provided with a stopping part 14, and the stopping part 14 stops the limiting body 11 at a blocking position of the object 20. Accordingly, the stopping part 14 can be used to avoid the situation that the limiting body 11 has oversteering, so as to maintain the stability of the limiting body 11 during operation.

In addition to the above embodiments, in one embodiment of the present disclosure, the body part 18 is provided with a restriction part 181, and the restriction part 181 restricts the limiting body 11 to a resisting position or a non-resisting position, wherein the restriction part 181 is a fastening body, a hole body, a groove body, a convex body, a concave body or a structure that can restrict a position. Accordingly, the restriction body 181 can be used to make the limiting body 11 be positioned in the required restriction position before or after the actuation, so as to avoid the situation that the limiting body 11 has oversteering, so as to maintain the stability of the limiting body 11 during operation.

In addition to the above embodiments, in one embodiment of the present disclosure, the body part 18 is provided with at least one combination part 182. Accordingly, the heat dissipation body 10 can be stably combined with the body part 18 by the combination part 182 cooperating with a fixing element 183.

In addition to the above embodiments, in one embodiment of the present disclosure, the number of the limiting body 11 is two or more, and the limiting bodies 11 and the body 18 therebetween are bolted, assembled or axially connected by the connecting part 15 cooperating with the pivot 16, so that the limiting bodies 11 are linked to the body 18 by the connecting part 15 to form a linkage, and the connecting part 15 below abuts against the object 20. Accordingly, the limiting bodies 11 can be rotated, and then the heat dissipation body 10 is elastically pressed downward and contacts the heating element 30 for heat dissipation. Accordingly, the heat dissipation body 10 can combine or separate the object 20 and the heating element 30 by using the limiting structure 1, and complete the quick combination of at least two objects, so as to achieve the purpose of combining and separating repeatedly and quickly.

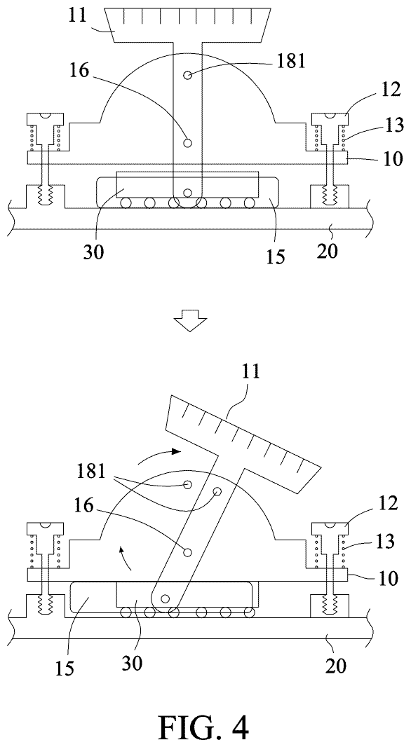

Referring to FIG. 4, as shown in the drawing, in addition to the above embodiments, in one embodiment of the present disclosure, the heat dissipation body 10 is provided with a restriction part 181, and the restriction part 181 restricts the limiting body 11 to a resisting position or a non-resisting position, wherein the restriction part 181 is a fastening body, a hole body, a groove body, a convex body, a concave body or a structure that can restrict a position. Accordingly, the restriction body 181 can be used to make the limiting body 11 be positioned in the required restriction position before or after the actuation, so as to avoid the situation that the limiting body 11 has oversteering, so as to maintain the stability of the limiting body 11 during operation.

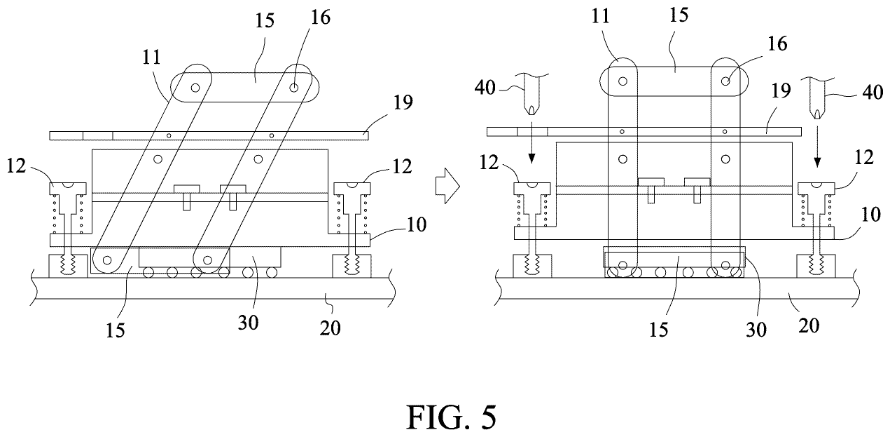

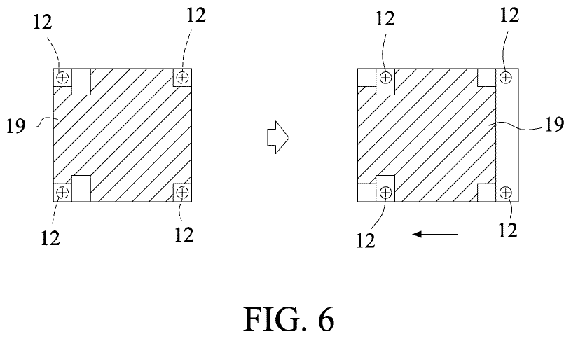

Referring to FIG. 5 and FIG. 6, as shown in the drawings, in addition to the above embodiments, in one embodiment of the present disclosure, the limiting body 11 of the limiting structure 1 is provided with a safety device 19, and the safety device 19 can actuate with the movement or rotation of the limiting body 11, so that when the limiting body 11 is limited to the heat dissipation body 10 has a distance h from the heating element 30 (or when the limiting body 11 restricts the elastic force or cushioning force exerted by the heat dissipation body 10 on the heating element 30), a tool 40 (or non-tool, or manual control) is not stopped to operate the fastening body 12, or when the limiting body 11 is not limited to the heat dissipation body 10 has a distance from the heating element 30 (or when the limiting body 11 restricts the elastic force or cushioning force exerted by the heat dissipation body 10 on the heating element 30), a tool 40 (or non-tool, or manual control) is stopped to operate the fastening body. Accordingly, the safety device 19 can be used to make the combination of the fastening body 12 and the object 20 further meet the needs of practical application.

In addition to the above embodiments, in one embodiment of the present disclosure, the safety device 19 is bolted (or assembled) to the limiting body 11 (or the limiting structure 1, or the heat dissipation body 10) by at least one bolt body 191. Accordingly, the limiting body 11 can drive the safety device 19 when it is actuated, so that when the limiting body 11 is limited to the heat dissipation body 10 has a distance h from the heating element 30, a tool 40 is not stopped to operate the fastening body 12, or when the limiting body 11 is not limited to the heat dissipation body 10 has a distance from the heating element 30, a tool 40 is stopped to operate the fastening body. Accordingly, the safety device 19 can be used to make the combination of the fastening body 12 and the object 20 further meet the needs of practical application.

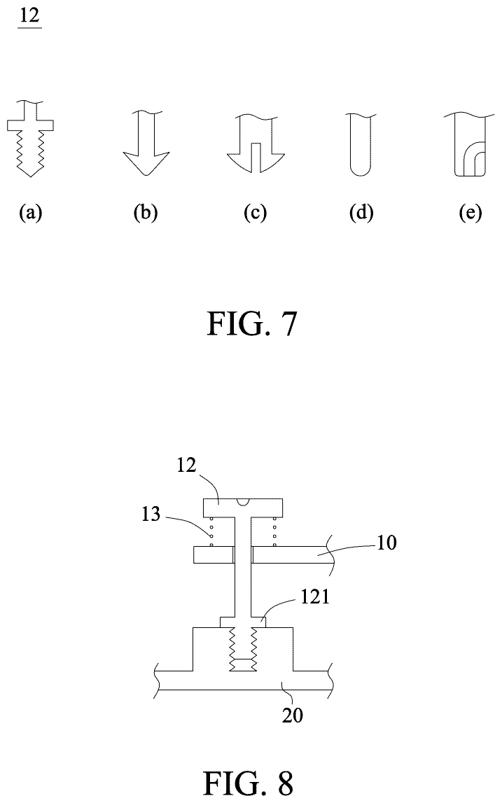

Referring to FIG. 7, as shown in the drawing, in addition to the above embodiments, in one embodiment of the present disclosure, the fastening body 12 may be a threaded body (as shown in part a of FIG. 7), an outer fastening body (as in part b of FIG. 7), an elastic fastening body (as in part c of FIG. 7), a rod body (as in part d of FIG. 7), an inner fastening body (as in part e of FIG. 7), a fastening body with a limiting height. Accordingly, the fastening body 12 can further meet the needs of practical use.

Referring to FIG. 8, as shown in the drawing, in addition to the above embodiments, in one embodiment of the present disclosure, the fastening body 12 may be a fastening body with a limiting height, and in the present embodiment, the fastening body 12 is provided with a blocking part 121, and the blocking part 121 restricts a depth, height or stroke of the fastening body 12 fastening into the object 20, or the blocking part 121 gives the elastic element 13 or the cushioning element storage, setting, reserved height, stroke, pressure height or pressure stroke. Accordingly, the fastening body 12 can further meet the needs of practical use.

While the present invention has been described by means of specific embodiments, those skilled in the art should understand the above description is merely embodiments of the invention, and it should not be considered to limit the scope of the invention. It should be noted that all changes and substitutions which come within the meaning and range of equivalency of the embodiments are intended to be embraced in the scope of the invention. Therefore, the scope of the invention is defined by the claims.

What is claimed is:

1. A limiting structure, comprising:
at least one limiting body and at least one heat dissipation body, the limiting body is combined with the heat dissipation body; and
at least one fastening body, disposed at the limiting structure, or an elastic element or cushioning element is disposed between the fastening body and the limiting structure, the fastening body is used to combine with an object, so that the limiting structure is limited to the object, the limiting body directly abuts against the body to make the heat dissipation body have a distance from a heating element of the object.

2. The limiting structure according to claim 1, wherein the limiting body is provided with a body part, the body part is combined with the heat dissipation body, or the body part is integrally formed with the heat dissipation body, or the limiting body is combined with the heat dissipation body.

3. The limiting structure according to claim 1, wherein the limiting body, or a body part of the limiting body or the heat dissipation body is provided with a stopping part, the stopping part stops the limiting body at a blocking position of the object.

4. The limiting structure according to claim 1, wherein the limiting body, or a body part of the limiting body or the heat dissipation body is provided with a restriction part, the restriction part restricts the limiting body at a resisting position or a non-resisting position.

5. The limiting structure according to claim 4, wherein the restriction part is a fastening body, a hole body, a groove body, a convex body, a concave body or a structure that can restrict a position.

6. The limiting structure according to claim 1, wherein the number of the limiting body is two or more, or at least one connecting part is respectively disposed between the limiting bodies, or the limiting bodies are linked with the connecting part.

7. The limiting structure according to claim 6, wherein the limiting bodies therebetween, the limiting bodies and the connecting part therebetween, the limiting bodies and the heat dissipation body therebetween, or the limiting bodies and a body part therebetween are bolted, assembled or axially connected.

8. The limiting structure according to claim 1, wherein the limiting body is blocked against the object, the limiting body is a single-piece structure, or the limiting body is a multi-piece connecting structure.

9. The limiting structure according to claim 1, wherein the heating element is a chip, an IC, a memory, a circuit board or a current device, or the object is a circuit board, or a server, a data center, a storage, a computer or a current device, or the heat dissipation body is a heat sink, a liquid cooling device, a radiator or a metal body.

10. The limiting structure according to claim 1, wherein an elastic body is disposed between the limiting body and the heat dissipation body, the elastic body makes the limiting body elastically located in a resisting position or a non-resisting position.

11. The limiting structure according to claim 1, wherein the limiting structure is provided with a safety device, the safety device actuates with the movement or rotation of the limiting body, so that when the limiting body is limited to that the heat dissipation body has a distance from the heating element, or when the limiting body restricts the elastic force or cushioning force exerted by the heat dissipation body on the heating element, a tool, non-tool or manual control is not stopped to operate the fastening body, or when the limiting body is not limited to that the heat dissipation body has a distance from the heating element, or when the elastic force or cushioning force exerted by the heat dissipation body on the heating element is not restricted, a tool, non-tool or manual control is stopped to operate the fastening body.

12. The limiting structure according to claim 1, wherein the limiting structure is provided with a safety device, the safety device is bolted or assembled to the limiting structure, the limiting body or the heat dissipation body.

13. The limiting structure according to claim 1, wherein the limiting body is a column, a metal body, a plastic body, a rod body, a bolted body or a buckle body, or the fastening body is a threaded body, an elastic fastening body, a rod body, an outer fastening body, an inner fastening body, a fastening body with a limiting height, or the elastic element is a spring, a coil spring, an elastic column or an element with cushioning characteristics.

14. The limiting structure according to claim 1, wherein the fastening body presses down the elastic element or the cushioning element, so that the elastic element or the cushioning element presses down the heat dissipation body to contact the heating element to dissipate heat.

15. The limiting structure according to claim 1, wherein the fastening body is provided with a blocking part, the blocking part restricts a depth, height or stroke of the fastening body fastening into the object, or the blocking part gives the elastic element or the cushioning element storage, setting, reserved height, stroke, pressure height or pressure stroke.

16. A limiting method of a limiting structure, limiting by the limiting structure as claimed in claim 1, wherein the limiting body is combined with the heat dissipation body with a downward pressure elastic force or with a cushioning element, and combined to the object by the fastening body, so that the limiting body is limited to the object, and the heat dissipation body has a distance from the heating element of the object, or the elastic force or cushioning force exerted by the heat dissipation body on the heating element is restricted, and then the limiting body is rotated or moved, so that the heat dissipation body is elastically pressed downward, pressed downward or contacts the heating element for heat dissipation, or the restriction of elasticity or cushioning force of the heat dissipation body is released for heat dissipation with the heating element, or the heat dissipation body is allowed to contact the heating element for heat dissipation.

17. A limiting method of a limiting structure, limiting by the limiting structure as claimed in claim 1, wherein the limiting body is used to make the heat dissipation body contact the heating element with uniform force, pressure, downward pressure or clastic downward pressure to be used for heat dissipation.
